(19) United States
(12) Patent Application Publication
(10) Pub. No.: US 2025/0072253 A1
(43) Pub. Date: Feb. 27, 2025

(54) DISPLAY APPARATUS

(71) Applicant: Samsung Display Co., Ltd., Yongin-si (KR)

(72) Inventors: Sanghoon Kim, Yongin-si (KR); Yeonju Kang, Yongin-si (KR); Sangshin Lee, Yongin-si (KR); Seungjin Lee, Yongin-si (KR)

(21) Appl. No.: 18/740,271

(22) Filed: Jun. 11, 2024

(30) Foreign Application Priority Data
Aug. 22, 2023 (KR) 10-2023-0110138

(51) Int. Cl. H10K 59/35; H10K 59/122

(52) U.S. Cl. CPC H10K 59/353; H10K 59/122

(57) ABSTRACT

Provided is a display apparatus including a substrate including quadrilateral unit areas repeatedly arranged in a first direction and a second direction, a first subpixel for emitting a first color and including a first sub emission area and a second sub emission area, a second subpixel for emitting a second color and including a second emission area adjacent to the first sub emission area in the first direction, a third subpixel for emitting a third color and including a third emission area adjacent to the first sub emission area in the second direction, wherein the first sub emission area includes a 1st-1 edge that that generally extends in the first direction and is concave, a 1st-2 edge that that generally extends in the second direction and is concave, and a first protrusion connecting the 1-1st edge to the 1st-2 edge.

### CROSS-REFERENCE TO RELATED APPLICATION

The present application claims priority to, and the benefit of, Korean Patent Application No. 10-2023-0110138, filed on Aug. 22, 2023, in the Korean Intellectual Property Office, the entire disclosure of which is incorporated herein by reference.

### BACKGROUND

### 1. Field

The disclosure relates to a display apparatus in which an emission area is enlarged such that a deposition efficiency during a manufacturing process is improved.

### 2. Description of the Related Art

An organic light-emitting display apparatus is a display apparatus configured to implement an image through light generated in an emission layer interposed between a pixel electrode and an opposite electrode. In such an organic light-emitting display apparatus, to control the light emission or level of light emission of each pixel, the pixel electrode is electrically connected to a thin-film transistor, and an electrical signal applied to the pixel electrode is controlled through the thin-film transistor.

### SUMMARY

However, in such an organic light-emitting display apparatus, as suitability for high resolution has increased, the size of the subpixel is reduced, and accordingly, emitting light with adequate luminance in the subpixel becomes difficult.

The disclosure provides a display apparatus in which an emission area is increased and a deposition efficiency is improved. However, this is merely an example, and the scope of the disclosure is not limited thereby.

Additional aspects will be set forth in part in the description which follows and, in part, will be apparent from the description, or may be learned by practice of the presented embodiments.

According to one or more embodiments, a display apparatus includes a substrate including quadrilateral unit areas repeatedly arranged in a first direction, and in a second direction perpendicular to the first direction, a first subpixel for emitting a first color, and including a first sub emission area and a second sub emission area spaced apart from each other at one of the unit areas, a second subpixel for emitting a second color, and including a second emission area adjacent to the first sub emission area in the first direction at the one of the unit areas, and a third subpixel for emitting a third color, and including a third emission area adjacent to the first sub emission area in the second direction at the one of the unit areas, wherein the first sub emission area includes a 1st-1 edge that generally extends in the first direction and that is concave, a 1st-2 edge that generally extends in the second direction and that is concave, and a first protrusion connecting the 1st-1 edge to the 1st-2 edge.

The first protrusion may be convex in a third direction crossing the first direction and the second direction.

The first sub emission area may be less than the second emission area and the third emission area.

The second emission area may include a 2nd-1 edge that generally extends in the first direction and that is convex, and a 2nd-2 edge that generally extends in the second direction and that is convex.

The third emission area may include a 3rd-1 edge that generally extends in the first direction and that is convex, and a 3rd-2 edge that generally extends in the second direction and that is convex.

A length of the 2nd-1 edge may be substantially equal to a length of the 2nd-2 edge, wherein a length of the 3rd-1 edge is substantially equal to a length of the 3rd-2 edge.

The second emission area may include a second protrusion at which the 2nd-1 edge and the 2nd-2 edge meet, wherein the third emission area includes a third protrusion at which the 3rd-1 edge and the 3rd-2 edge meet.

The second protrusion and the third protrusion may each have a pointed shape in a third direction crossing the first direction and the second direction.

A size of the second sub emission area may be substantially equal to a size of the first sub emission area.

The second sub emission area may have a shape in which the first sub emission area is rotated by 90 degrees.

The display apparatus may further include a pixel-defining layer above the substrate, covering at least a portion of a pixel electrode of the first subpixel, and defining openings defining the first sub emission area and the second sub emission area.

The pixel electrode of the first subpixel may include a first sub pixel electrode corresponding to the first sub emission area, and a second sub pixel electrode corresponding to the second sub emission area, wherein the first sub pixel electrode and the second sub pixel electrode are electrically connected to each other.

The unit areas may have a substantially square shape.

According to one or more embodiments, a display apparatus includes a substrate including quadrilateral unit areas repeatedly arranged in a first direction, and in a second direction perpendicular to the first direction, a first subpixel for emitting a first color, and including a first sub emission area and a second sub emission area spaced apart from each other at one of the unit areas, a second subpixel for emitting a second color at the one of the unit areas, and including a second emission area having a size that is greater than a size of the first sub emission area, and a third subpixel for emitting a third color at the one of the unit areas, and including a third emission area having a size that is greater than a size of the first sub emission area, wherein the first sub emission area includes a 1st-1 edge that generally extends in the first direction and that is convex, and a 1st-2 edge that generally extends in the second direction and that is convex, wherein the second emission area includes a 2nd-1 edge that generally extends in the first direction and that is convex, and a 2nd-2 edge that generally extends in the second direction and that is convex, and wherein the third emission area includes a 3rd-1 edge that generally extends in the first direction and that is convex, and a 3rd-2 edge that generally extends in the second direction and that is convex.

The first sub emission area and the second sub emission area may be adjacent to each other in a third direction crossing the first direction and the second direction, wherein the second emission area and the third emission area are adjacent to each other in a fourth direction that is perpendicular to the third direction.

The second sub emission area may have a shape in which the first sub emission area is rotated by 90 degrees.

The first sub emission area may include a first protrusion connecting the 1st-1 edge to the 1st-2 edge, wherein the second emission area includes a second protrusion at which the 2nd-1 edge and the 2nd-2 edge meet, wherein the third emission area includes a third protrusion at which the 3rd-1 edge and the 3rd-2 edge meet, wherein the first protrusion is convex in a third direction crossing the first direction and the second direction, and wherein the second protrusion and the third protrusion have a pointed shape in the third direction.

A length of the 2nd-1 edge may be substantially equal to a length of the 2nd-2 edge, wherein a length of the 3rd-1 edge is substantially equal to a length of the 3rd-2 edge.

The display apparatus may further include a pixel-defining layer above the substrate, covering at least a portion of a pixel electrode of the first subpixel, and defining openings defining the first sub emission area and the second sub emission area.

The pixel electrode of the first subpixel may include a first sub pixel electrode corresponding to the first sub emission area, and a second sub pixel electrode corresponding to the second sub emission area, wherein the first sub pixel electrode and the second sub pixel electrode are electrically connected to each other.

Aspects other than those described above will become apparent from the following detailed description, the appended claims, and the accompanying drawings.

### BRIEF DESCRIPTION OF THE DRAWINGS

The above and other aspects of embodiments of the disclosure will be more apparent from the following description taken in conjunction with the accompanying drawings, in which:

FIG. 1 is a schematic plan view of a display apparatus according to one or more embodiments;

FIGS. 2 to 4 are each a cross-sectional view schematically illustrating a portion of the display apparatus according to one or more embodiments;

FIG. 5 is an equivalent circuit diagram of a pixel included in the display apparatus according to one or more embodiments;

FIG. 6 is a schematic plan view of a display apparatus according to one or more embodiments;

FIG. 7 is a schematic plan view of a portion of the display apparatus according to one or more embodiments;

FIGS. 8A and 8B are schematic plan views of comparative examples for explaining characteristics of one or more embodiments;

FIG. 9 is a table for explaining an opening rate of the display apparatus and comparative examples according to one or more embodiments; and

FIG. 10 is a cross-sectional view schematically illustrating a portion of the display apparatus, according to one or more embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing one or more embodiments corresponds to one or more embodiments of the present disclosure. The present disclosure covers all modifications, equivalents, and replacements within the idea and technical scope of the present disclosure. Further, each of the features of the various embodiments of the present disclosure may be combined with each other, in part or in whole, and technically various interlocking and driving are possible. Each embodiment may be implemented independently of each other or may be implemented together in an association.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

In the following embodiments, the expression “a line extends in a first direction or a second direction” may include a case in which “a line extends in a linear shape” and a case in which “a line extends in a zigzag or curved shape in a first direction or a second direction.”

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

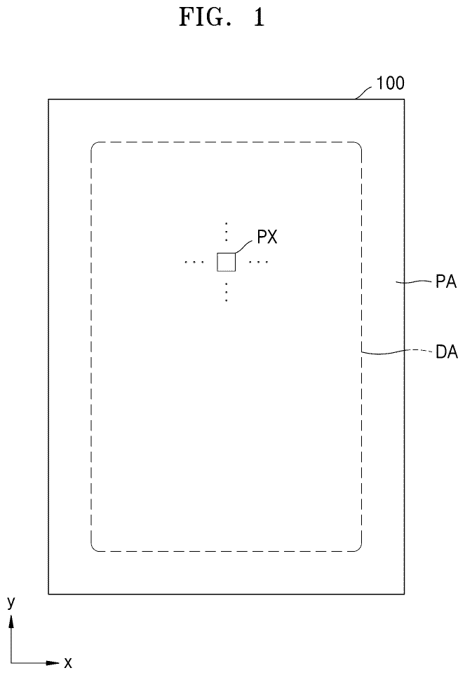

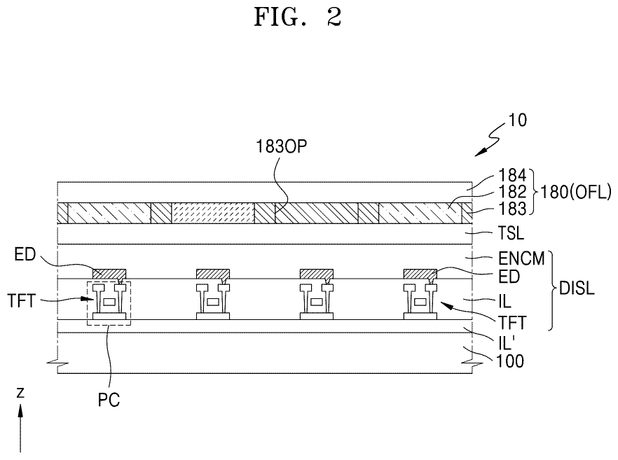

FIG. 1 is a plan view schematically illustrating a display apparatus according to one or more embodiments. FIGS. 2 to 4 are each a cross-sectional view schematically illustrating a portion of the display apparatus according to one or more embodiments.

Referring to FIG. 1, the display apparatus may include a display panel 10. In one or more embodiments, a cover window for protecting the display panel 10 may be arranged on an upper portion of the display panel 10.

The display panel 10 may include a display area DA for implementing an image, and a peripheral area PA outside the display area DA. The peripheral area PA may be a type of non-display area in which pixels are not arranged. The display area DA may be entirely surrounded by the peripheral area PA (e.g., in plan view). Various elements included in the display panel 10 may be located on the substrate 100. Thus, it is apparent that the substrate 100 includes the display area DA and the peripheral area PA.

A plurality of pixels PX may be arranged in the display area DA. The pixels PX may include a display element. The display element may be connected to a pixel circuit that is configured to drive the pixels PX. In one or more embodiments, the display element may be an organic light-emitting diode OLED. Each of the pixels PX may emit, for example, red, green, blue, or white light through the organic light-emitting diode OLED.

In a plan view, the display area DA may have a rectangular shape as illustrated in FIG. 1. In some embodiments, the display area DA may have a polygonal shape, such as triangle, pentagon, hexagon, etc. or a circular shape, an ellipse, an irregular shape, etc.

The peripheral area PA, which is an area arranged around the display area DA, may be an area where an image is not displayed. Various lines configured to transmit electric signals to be applied to the display area DA, external circuits electrically connected to the pixel circuits, and pads on which a printed circuit board or a driver IC chip is attached may be arranged in the peripheral area PA.

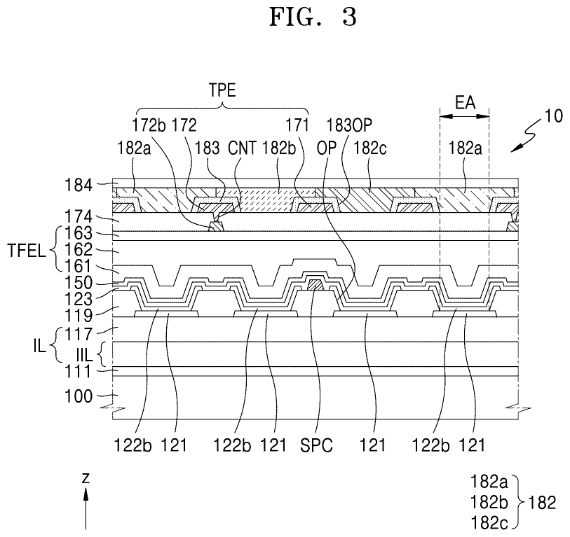

Referring to FIGS. 2 and 3, the display panel 10 may include a substrate 100, a display layer DISL on the substrate 100, a touch screen layer TSL, and an optical functional layer OFL.

In one or more embodiments, the display layer DISL may include a pixel circuit PC including a thin-film transistor TFT, a light-emitting element ED that is a display element, and an encapsulation material ENCM, such as a thin-film encapsulation layer TFEL or an encapsulation substrate. Insulating layers IL and IL′ may be respectively arranged in the display layer DISL, and between the substrate 100 and the display layer DISL. For convenience of illustration, the pixel circuit PC was omitted in FIG. 3.

The substrate 100 may have a single-layer structure formed of a glass material. Alternatively, the substrate 100 may include a polymer resin. The substrate 100 including a polymer resin may have a multi-layer structure in which an organic layer including a polymer resin and an inorganic layer are stacked. The substrate 100 may include a rigid substrate or a flexible substrate that is bendable, foldable, rollable, etc.

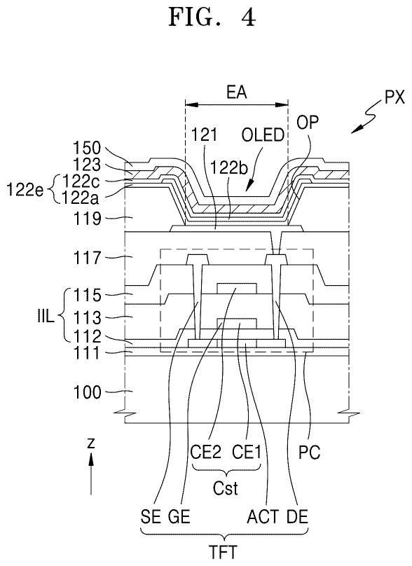

A buffer layer 111, an inorganic insulating layer IL, and a planarization layer 117 may be sequentially stacked on the substrate 100. The planarization layer 117 may include an organic material or an inorganic material, and may have a single-layer structure or a multi-layer structure. The pixel circuit PC may be arranged between the buffer layer 111 and the planarization layer 117. As shown in FIG. 4, the pixel circuit PC may include the thin-film transistor TFT and a capacitor Cst.

The thin-film transistor TFT may include a semiconductor layer ACT including an organic semiconductor material, such as an amorphous silicon, a polycrystalline silicon, an oxide semiconductor material, a gate electrode GE, a source electrode SE, and a drain electrode DE. The capacitor Cst may include a lower electrode CE1 and an upper electrode CE2.

The semiconductor layer ACT may be located on the buffer layer 111. A first insulating layer 112 may be arranged between the semiconductor layer ACT and the gate electrode GE. A second insulating layer 113 may be located on the gate electrode GE. The upper electrode CE2 of the capacitor Cst may be located on the second insulating layer 113. The upper electrode CE2 may overlap the gate electrode GE thereunder. The gate electrode GE and the upper electrode CE2 overlapping each other with the second insulating layer 113 therebetween may constitute the capacitor Cst. The gate electrode GE may be the lower electrode CE1 of the capacitor Cst. A third insulating layer 115 may be located on the capacitor CST. The source electrode SE and the drain electrode DE may be located on the third insulating layer 115.

The first insulating layer 112, the second insulating layer 113, and the third insulating layer 115 may each include inorganic substances, such as silicon oxide, silicon nitride, and/or silicon oxynitride. The first insulating layer 112, the second insulating layer 113, and the third insulating layer 115 may be called an inorganic insulating layer IL.

A buffer layer 111 including an inorganic material, such as silicon oxide, silicon nitride, and/or silicon oxynitride may be arranged between the thin-film transistor TFT and the substrate 100.

The planarization layer 117 may be on the thin-film transistor TFT. The planarization layer 117 may include an organic insulating material, such as acryl, benzocyclobutene (BCB), or hexamethyldisiloxane (HMDSO). The planarization layer 117 may include an inorganic insulating material, such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂). When the planarization layer 117 is formed, to provide a flat upper surface after forming a layer, chemical mechanical polishing may be performed on an upper surface of the layer. The planarization layer 117 may include a single layer or multiple layers.

As a light-emitting element ED, the organic light-emitting diode OLED, which is a display element, may be arranged on the planarization layer 117. The organic light-emitting diode OLED may include a pixel electrode 121, an opposite electrode 123, and an intermediate layer between the pixel electrode 121 and the opposite electrode 123.

The pixel electrode 121 may be located on the planarization layer 117, and the pixel electrode 121 may be in contact with the source electrode SE or the drain electrode DE through a via hole of the planarization layer 117 to be electrically connected to the thin-film transistor TFT.

A pixel-defining layer 119 may be located on the planarization layer 117. The pixel-defining layer 119 may include an opening OP covering edges of the pixel electrode 121, and exposing a portion of the pixel electrode 121. The size and shape of an emission area EA of the organic light-emitting diode OLED may be defined by the opening OP.

The pixel-defining layer 119 may include a transparent insulating material or opaque insulating material. In one or more embodiments, the pixel-defining layer 119 may include an organic insulating material, such as polyimide, polyamide, acrylic resin, benzocyclobutene, hexamethyldisiloxane (HMDSO), or phenol resin. In some embodiments, the pixel-defining layer 119 may include an inorganic insulating material, such as silicon nitride or a silicone oxide, or may include an organic insulating material and an inorganic insulating material.

In one or more embodiments, the pixel-defining layer 119 may include a light-blocking material, and may be provided in black. The light shield material may include resin or paste including carbon black, carbon nanotube, or black dye, may include metal particles, for example, nickel, aluminum, molybdenum, and/or an alloy thereof, may include metal oxide particles, for example, a chromium oxide, and/or may include metal nitride particles, for example, a chromium nitride, and the like. When the pixel-defining layer 119 includes a light-blocking material, the reflection of external light due to metal structures under the pixel-defining layer 119 may be reduced.

As shown in FIG. 3, a spacer SPC may be located on the pixel-defining layer 119. In one or more embodiments, the spacer SPC may include the same material as the pixel-defining layer 119. In this case, the pixel-defining layer 119 and the spacer SPC may be formed together in a mask process using a half-tone mask, such that the spacer SPC may have an island shape protruding apart from the pixel-defining layer 119 in a z direction. In some embodiments, the spacer SPC may include a material that is different from the pixel-defining layer 119. In this case, the spacer SPC may be island-shaped insulating patterns spaced apart from each other by a certain distance on the pixel-defining layer 119.

As shown in FIG. 4, the intermediate layer may include an emission layer 122b and an organic functional layer over and/or under the emission layer 122b.

The emission layers 122b may correspond to the pixel electrode 121 in the opening OP of the pixel-defining layer 119. The emission layer 122b may include a polymer material or a low molecular weight material, and may emit red, green, blue, or white light.

The organic functional layer 122e may include a first functional layer 122a and/or a second functional layer 122c. The first functional layer 122a or the second functional layer 122c may be omitted.

The first functional layer 122a may be arranged under the emission layer 122b. The first functional layer 122a may have a single-layer or multi-layer structure including an organic material. The first functional layer 122a may be a hole transport layer (HTL) having a single-layer structure. Alternatively, the first functional layer 122a may include a hole injection layer (HIL) and an HTL. The first functional layer 122a may be integrally formed to correspond to organic light-emitting diodes OLED included in the display area DA.

The second functional layer 122c may be arranged on the emission layer 122b. The second functional layer 122c may have a single-layer or multi-layer structure including an organic material. The second functional layer 122c may include an electron transport layer (ETL) and/or an electron injection layer (EIL). The second functional layer 122c may be integrally formed to correspond to organic light-emitting diodes OLED included in the display area DA.

The opposite electrode 123 may be located on the emission layer 122b. An upper layer 150 including an organic material may be formed on the opposite electrode 123.

In one or more embodiments, the intermediate layer may include two or more emitting units sequentially stacked between the pixel electrode and the opposite electrode 123, and may include a charge generation layer (CGL) arranged between two emitting units. When the intermediate layer includes an emitting unit and a charge generation layer, the organic light-emitting diode OLED may be a tandem light-emitting element. The organic light-emitting diode OLED may have improved color purity and emission efficiency by including a stacked structure of a plurality of emitting units.

One emitting unit may include the emission layer 122b, along with the first functional layer 122a and the second function layer 122c respectively located over and under the emission layer 122b. The charge generation layer may include a negative charge generation layer and a positive charge generation layer. The luminous efficiency of the organic light-emitting diode OLED, which is a tandem light-emitting element including a plurality of emission layers, may be further increased by the negative charge generation layer and the positive charge generation layer. The negative charge generation layer may be an n-type charge generation layer. The negative charge generation layer may supply electrons. The negative charge generation layer may include a host and a dopant. The host may include an organic material. The dopant may include a metal material. The positive charge generation layer may be a p-type charge generation layer. The positive charge generation layer may supply holes. The positive charge generation layer may include a host and a dopant. The host may include an organic material. The dopant may include a metal material.

The upper layer 150 may protect the opposite electrode 123, and may improve light extraction efficiency. The upper layer 150 may include lithium fluoride (LiF). Alternatively, the upper layer 150 may additionally include an inorganic insulating material, such as silicon oxide (SiO₂) or silicon nitride (SiNₓ).

The display elements may be covered with the thin-film encapsulation layer TFEL. In one or more embodiments, the thin-film encapsulation layer TFEL may include at least one inorganic encapsulation layer and at least one organic encapsulation layer. For example, the thin-film encapsulation layer TFEL may include a first inorganic encapsulation layer 161, a second inorganic encapsulation layer 163, and an organic encapsulation layer 162 therebetween.

The touch screen layer TSL (e.g., see FIG. 2) may be located on the second inorganic encapsulation layer 163. The touch screen layer TSL may be configured to obtain coordinate information according to an external input, for example, a touch event. The touch screen layer TSL may sense an external input by using a self-capacitance method or a mutual capacitance method. The touch screen layer TSL may include touch electrodes TPE and lines connected to the touch electrodes TPE. The touch electrodes TPE may include first touch electrodes 171 and second touch electrodes 172. The first touch electrodes 171 may be connected by first connection electrodes placed on the same layer as the first touch electrodes 171. The second touch electrodes 172 may be connected by second connection electrodes 172b located on a different layer from the second touch electrodes 172 via a contact hole CNT of an insulating layer 174. The touch electrodes TPE may correspond to respective portions of the pixel-defining layer 119.

The optical functional layer OFL may include a filter layer 180 including a color filter 182, a black matrix 183, and an overcoat layer 184. The black matrix 183 may cover the first touch electrodes 171 and the second touch electrodes 172. The black matrix 183 may be arranged to correspond to the pixel-defining layer 119. The overcoat layer 184 may include an organic material, such as resin and the organic material may be transparent.

In the display panel 10 using the color filter 182 and the black matrix 183 as the optical functional layer OFL instead of the polarizer and the polarization film, the emission efficiency of the display element may be improved, thereby resulting in a reduction of power consumption and an increase of luminance, and thus improving the lifespan of the display panel. In addition, the same or greater luminance/lifespan may be achieved even with an emission area that is smaller than that of the related art. In addition, because the polarizer or the polarization film is not used, the thickness of the display panel may be reduced.

The color filter 182 may include a first color filter 182a configured to selectively transmit only light of a first color, a second color filter 182b configured to selectively transmit only light of a second color, and a third color filter 182c configured to selectively transmit only light of a third color. The first color filter 182a, the second color filter 182b, and the third color filter 182c may be arranged correspondingly to the emission area EA of the subpixel PX. The first color filter 182a, the second color filter 182b, and the third color filter 182c may be arranged adjacent to each other. Each of the first color filter 182a, the second color filter 182b, and the third color filter 182c may have an independent pattern structure. Each of the first color filter 182a, the second color filter 182b, and the third color filter 182c may be arranged in an opening 183OP of the black matrix 183. Each of the first color filter 182a, the second color filter 182b and the third color filter 182c may overlap a portion of the pixel-defining layer 119.

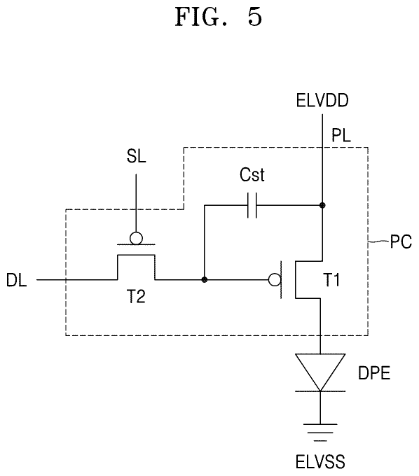

FIG. 5 is an equivalent circuit diagram of a pixel included in the display apparatus according to one or more embodiments.

Referring to FIG. 5, the pixel circuit PC may include a driving transistor T1, a scan transistor T2, and a storage capacitor Cst. In one or more embodiments, the driving transistor T1 and the scan transistor T2 may be a thin-film transistor.

The scan transistor T2 may be electrically connected to each of a scan line SL and a data line DL, and may be configured to transmit, to the first thin-film transistor T1, a data voltage input from the data line DL, based on a scan signal input from the scan line SL. The storage capacitor Cst may be electrically connected to the scan transistor T2 and a driving voltage line PL, and may be configured to store a voltage corresponding to a difference between a voltage received from the scan transistor T2 and a driving voltage ELVDD supplied to the driving voltage line PL.

The driving transistor T1 may be electrically connected to the driving voltage line PL and the storage capacitor Cst and may control a driving current flowing through the display element ED from the driving voltage line PL in response to a voltage value stored in the storage capacitor Cst. The display element ED may emit light having certain luminance according to the driving current. A common voltage ELVSS may be supplied to an opposite electrode of the display element DPE. The display element DPE may be the organic light-emitting diode OLED of FIG. 4.

FIG. 5 shows that the pixel circuit PC includes two transistors and one storage capacitor, but the pixel circuit PC may include three or more transistors.

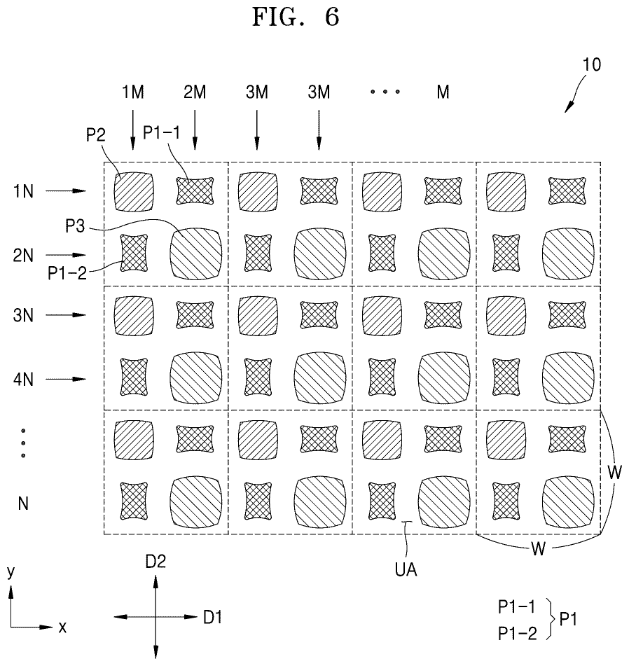

FIG. 6 is a schematic plan view of a portion of the display apparatus according to one or more embodiments, wherein the arrangement of the subpixels are shown. Referring to FIG. 6, the display panel 10 has a unit area UA having a quadrilateral shape. The unit area UA may be repeatedly arranged in a first direction D1 and a second direction D2 on the display panel 10. The second direction D2 may be perpendicular to the first direction D1. The first direction D1 may be a +x direction or a −x direction, and the second direction D2 may be a +y direction or a −y direction.

A plurality of subpixels may be arranged in the unit area UA. The subpixels may emit different respective colors, and may be, for example, one of a red subpixel, a green subpixel, and a blue subpixel. The first subpixel P1, the second subpixel P2, and the third subpixel P3, which emit different colors from each other, may be arranged in the unit area UA. Hereinafter, for convenience of explanation, the first subpixel P1 is a red subpixel, the second subpixel P2 is a green subpixel, and the third subpixel P3 is a blue subpixel.

In one unit area UA, the first subpixel P1, the second subpixel P2, and the third subpixel P3 may be apart from each other. The first subpixel P1 may include a first sub-subpixel P1-1 and a second sub-subpixel P1-2, and in this case, the first sub-subpixel P1-1, the second sub-subpixel P1-2, the second subpixel P2, and the third subpixel P3 may be apart from each other. The first sub-subpixel P1-1 and the second sub-subpixel P1-2 may be driven by one pixel circuit.

In the unit area UA, the first sub-subpixel P1-1 may be adjacent to the second subpixel P2 in the first direction D1, and adjacent to the third subpixel P3 in the second direction D2. The second sub-subpixel P1-2 may be adjacent to the second subpixel P2 in the second direction D2, and may be adjacent to the third subpixel P3 in the first direction D1. The first sub-subpixel P1-1 and the second sub-subpixel P1-2 may be arranged adjacent to each other in a third direction/diagonal direction crossing the first direction D1 and the second direction D2.

In other words, on the display panel 10, the second subpixel P2 and the first sub-subpixel P1-1 may be alternately arranged in a first row 1N, and the second sub-subpixel P1-2 and the third subpixel P3 may be alternately arranged in a second row 2N adjacent to the first row 1N. Also, the second subpixel P2 and the first sub-subpixel P1-1 may again be alternately arranged, as in the first row 1N, in a third row 3N adjacent to the second row 2N, and the second sub-subpixel P1-2 and the third subpixel P3 may again be alternately arranged, as in the second row 2N, in a fourth row 4N. Such an arrangement of the subpixels may be repeated until the Nth row.

In the same manner, the second subpixel P2 and the second sub-subpixel P1-2 may be alternately arranged in a first column 1M, and the second sub-subpixel P1-2 and the third subpixel P3 may be alternately arranged in a second column 2M adjacent to the first column 1M. Further, the second subpixel P2 and the second sub-subpixel P1-2 may again be alternately arranged, as in the first column 1M, in a third column 3M, and the second sub-subpixel P1-2 and the third subpixel P3 may again be alternately arranged, as in the second column 2M, in a fourth column 4M. Such an arrangement of the subpixels may be repeated until the Mth row.

In one or more embodiments, the unit area UA may have a square shape. As shown in FIG. 6, a width W in the first direction D1 of the unit area UA may be the same as the width W in the second direction D2 of the unit area UA. However, embodiments are not limited thereto. For example, the unit area UA may have a rectangular shape.

The emission area of the subpixels is an area where the emission layer of the organic light-emitting diode is arranged, and as described with reference to FIG. 4, the size and shape of the emission area EA of the organic light-emitting diode OLED may be defined by the opening OP of the pixel-defining layer 119. The arrangement (placement) of the pixels herein may refer to the arrangement (placement) of the display element, the arrangement (placement) of the pixel electrode, or the arrangement (placement) of the emission area. The size (area) of the pixel herein may refer to the size (area) of the emission area or the size of the opening OP of the pixel-defining layer 119.

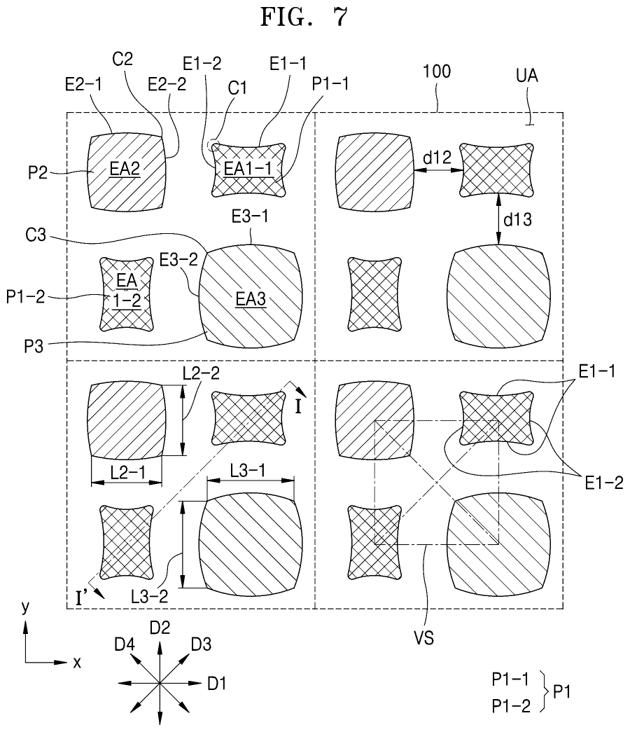

FIG. 7 is a schematic plan view of a portion of the display apparatus according to one or more embodiments, wherein the emission area of the subpixels are shown.

Referring to FIG. 7, the substrate 100 may include the unit area UA having a quadrilateral shape, and on the first sub-subpixel P1-1, the second sub-subpixel P1-2, the second subpixel P2, and the third subpixel P3 may be apart from each other on one unit area UA. The unit area UA may include a virtual quadrilateral shape VS of which the center point is the center point of the unit area UA. The first sub-subpixel P1-1, the second sub-subpixel P1-2, the second subpixel P2, and the third subpixel P3 may be respectively arranged on the vertices of the virtual quadrilateral shape VS.

The first subpixel P1 may include a first sub emission area EA1-1 corresponding to the first sub-subpixel P1-1 and a second sub emission area EA1-2 corresponding to the second sub-subpixel P1-2. The second subpixel P2 may include a second emission area EA2, and the third subpixel P3 may include a third emission area EA3.

In one or more embodiments, the size of the first sub emission area EA1-1 may be less than the size of the second emission area EA2 and the third emission area EA3. In one or more embodiments, the size of the second sub emission area EA1-2 may be less than the size of the second emission area EA2 and the third emission area EA3. The size of the second emission area EA2 may be less than the size of the third emission area EA3. The size of the first sub emission area EA1-1 may be the same as the size of the second sub emission area EA1-2.

In one or more embodiments, the first sub emission area EA1-1 may include a 1st-1 edge E1-1 that generally extends in the first direction D1, a 1st-2 edge E1-2 that generally extends in the second direction D2, and a first protrusion C1 connecting the 1st-1 edge E1-1 with the 1st-2 edge E1-2. Referring to FIG. 7, the first sub emission area EA1-1 may have a shape in which two 1st-1 edges E1-1 facing each other in the second direction D2, two 1st-2 edges E1-2 facing each other in the first direction D1, and four first protrusions C1 are connected to each other. The second sub emission area EA1-2 may have a shape wherein the first sub emission area EA1-1 is rotated by 90 degrees in a clockwise or counterclockwise direction.

The second emission area EA2 may include a 2nd-1 edge E2-1 that generally extends in the first direction D1, a 2nd-2 edge E2-2 that generally extends in the second direction D2, and a second protrusion C2 at which the 2nd-1 edge E2-1 and the 2nd-2 edge E2-2 meet. Referring to FIG. 7, the second emission area EA2 may have a shape in which two 2nd-1 edges E2-1 facing each other in the second direction D2 and two 2nd-2 edges E2-2 facing each other in the first direction D1 are connected to each other.

The third emission area EA3 may include a 3rd-1 edge E3-1 that generally extends in the first direction D1, a 3rd-2 edge E3-2 that generally extends in the second direction D2, and a third protrusion C3 at which the 3rd-1 edge E3-1 and the 3rd-2 edge E3-2 meet. Referring to FIG. 7, the third emission area EA3 may have a shape in which two 3rd-1 edges E3-1 facing each other in the second direction D2 and two 3rd-2 edges E3-2 facing each other in the first direction D1 are connected to each other.

Herein, an edge of the emission area being concave refers to the emission area being curved in an inner direction, and an edge of the emission area being convex refers to the emission area being curved in an outward direction.

In one or more embodiments, the first sub emission area EA1-1 may have an approximately concave quadrilateral shape. The 1st-1 edge E1-1 and the 2nd-2 edge E1-2 may have a concave shape. The 1st-1 edge E1-1 may be curved in the second direction D2 and the 1st-2 edge E1-2 may be curved in the first direction D1. The first protrusion C1 may be convex in an opposite direction toward the center of the first sub emission area EA1-1. A portion of the first protrusion C1 may be convex in the third direction D3, and the remaining portions may be convex in the fourth direction D4. The first sub emission area EA1-1 may have a shape in which four sides of a virtual rectangle are concave, and in which four vertices are convexly protruded.

The second emission area EA2 may have a substantially convex quadrilateral shape. The 2nd-1 edge E2-1 and the 2nd-2 edge E2-2 may have a convex shape. The 2nd-1 edge E2-1 may be curved in the second direction D2, and the 2nd-2 edge E2-2 may be a curved in the first direction D1. The second protrusion C2 may have a generally pointed shape due to the 2nd-1 edge E2-1 and the 2nd-2 edge E2-2 that are convex. A portion of the second protrusion C2 may be pointed in the third direction D3, and the remaining portions may be pointed in the fourth direction D4. The second emission area EA2 may have a shape in which four sides of a virtual rectangle are convex.

The third emission area EA3 may have a substantially convex quadrilateral shape. The 3rd-1 edge E3-1 and the 3rd-2 edge E3-2 may have a convex shape. The 3rd-1 edge E3-1 may be curved in the second direction D2, and the 3rd-2 edge E3-2 may be a curved in the first direction D1. The third protrusion C3 may have a generally pointed shape due to the 3rd-1 edge E3-1 and the 3rd-2 edge E3-2 that are convex. A portion of the third protrusion C3 may be pointed in the third direction D3, and the remaining portions may be pointed in the fourth direction D4. The second emission area EA2 may have a shape in which four sides of a virtual rectangle are convex.

The emission layer of the display element may be formed by depositing an emission material on the emission area defined by the opening of the pixel-defining layer by using a fine metal mask (FMM), and a deposition efficiency may vary according to the shape of the emission area. For example, vertex portions of a quadrilateral emission area may not be normally deposited, or the quadrilateral emission area may be deposited with round corners, thereby causing a reduction in an opening rate of a pixel. The same may apply to upper and/or lower material layers deposited correspondingly to the emission area.

According to one or more embodiments, the first subpixel P1, the second subpixel P2, and the third subpixel P3 may each have a shape in which the corner portion (vertex), at which an edge that extends in the first direction D1 and an edge that extends in the second direction D2 meet, is protruded, thereby resulting in increased deposition efficiency and opening rate. In addition, in one or more embodiments, because the edges of the first sub emission area EA1-1 are concave and the edges of the emission areas adjacent to the first sub emission area EA1-1 are convex, the opening rate is improved, and distances d12, d13, etc. between the subpixels are obtained, thereby reducing or preventing the likelihood of a defect in the deposition using the FMM.

In one or more embodiments, a length L2-1 of the 2nd-1 edge E2-1 and a length L2-2 of the 2nd-2 edge E2-2 may be the same. The length L2-1 of the 2nd-1 edge E2-1 and the length L2-2 of the 2nd-2 edge E2-2 may refer to the width or the curve length in the extending direction of each edge. A length L3-1 of the 3rd-1 edge E3-1 and a length L3-2 of the 3rd-2 edge E3-2 may be the same. The length L3-1 of the 3rd-1 edge E3-1 and the length L3-2 of the 3rd-2 edge E3-2 may refer to the width or the curve length in the extending direction of each edge.

When the lengths of the edges of the subpixel emission area are different from each other, because the reflection of light of a long edge and a short edge are different, viewing angle characteristics may be reduced.

According to one or more embodiments, because the edges of the second emission area EA2 have substantially the same lengths, and because the edges of the third emission area EA3 have substantially the same lengths, deterioration of viewing angle characteristics due to a difference between the light reflection according to a difference between the lengths of the edges may be reduced or prevented. In addition, as described above, the second sub emission area EA1-2 may have a shape wherein the first sub emission area EA1-1 is rotated by 90 degrees in a clockwise or anti-clockwise direction. Accordingly, even when the display panel 10 is used in a lengthened form from side to side or used in a rotated state, an image of suitable quality may be displayed.

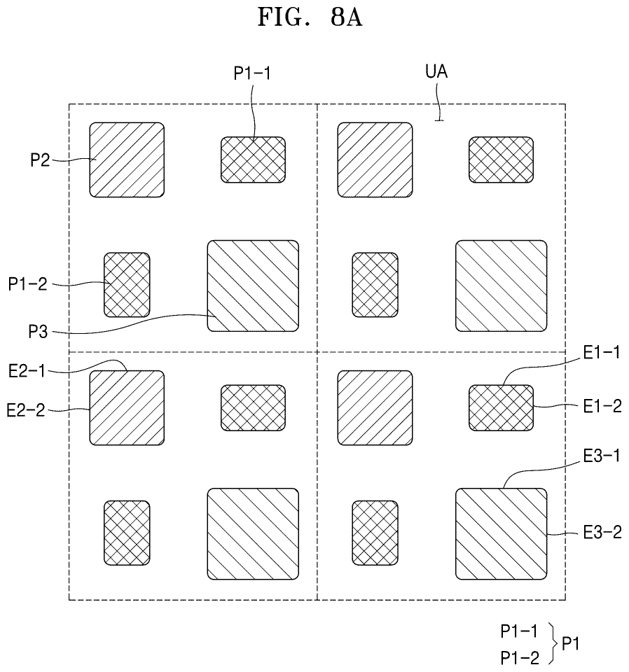

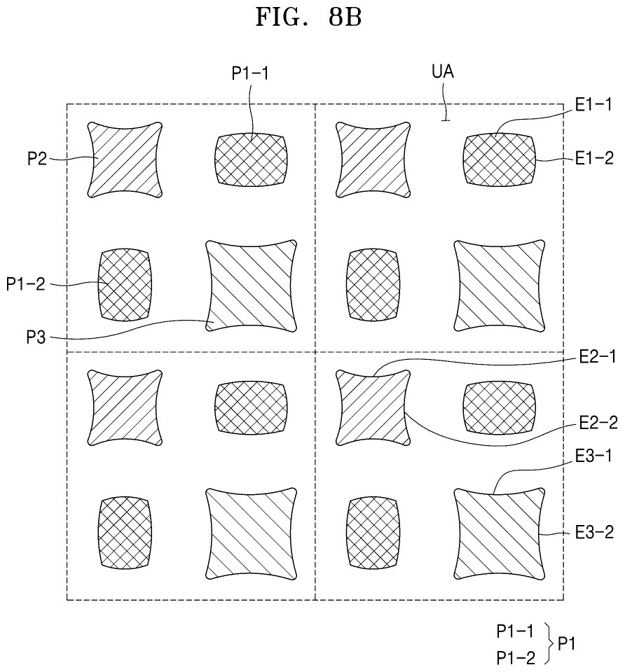

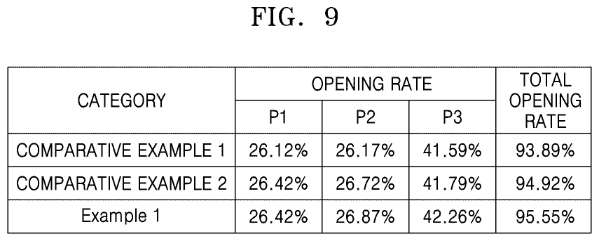

FIGS. 8A and 8B are each a plan view schematically illustrating a comparative example for explaining the characteristics of one or more embodiments, and FIG. 9 is a comparative table for explaining the opening rate of the display apparatus according to one or more embodiments and of the comparative examples. Comparative Example 1 of FIG. 9 refers to a comparative example of FIG. 8A, Comparative Example 2 refers to a comparative example of FIG. 8B, and the example (hereinafter referred to as Example 1) refers to the embodiments corresponding to FIG. 7.

FIG. 8A is a schematic plan view of Comparative Example 1, and FIG. 8B is a schematic plan view of Comparative Example 2. Comparative Example 1 and Comparative Example 2 have the same arrangement of subpixels and the same distances between the subpixels as those of Example 1, but are different from Example 1 in the shape of the emission area of the subpixels.

In the case of Comparative Example 1, the emission area of the first sub-subpixel P1-1, the second sub-subpixel P1-2, the second subpixel P2, and the third subpixel P3 each have a quadrilateral shape with chamfered vertices. The 1st-1 edge E1-1, the 1st-2 edge E1-2, the 2nd-1 edge E2-1, the 2nd-2 edge E2-2, the 3rd-1 edge E3-1, and the 3rd-2 edge E3-2 of the emission area of each subpixel are all straight, and the corner portion of the emission area may have a round or straight-edged shape.

In the case of Comparative Example 2, the emission area of the first sub-subpixel P1-1 and the second sub-subpixel P1-2 may each have a convex quadrilateral shape, and the emission area of the second subpixel P2 and the third subpixel P3 may each have a concave quadrilateral shape. In the case of Comparative Example 2, which is different from Example 1, the 1st-1 edge E1-1 and the 1st-2 edge E1-2 are convex, and the 2nd-1 edge E2-1, the 2nd-2 edge E2-2, the 3rd-1 edge E3-1, and the 3rd-2 edge E3-2 are concave.

FIG. 9 is a comparative table regarding the opening rate test of the pixel according to Comparative Example 1 of FIG. 8, according to Comparative Example 2 of FIG. 8B, and according to Example 1 of FIG. 7. The distance between the subpixels included in Comparative Example 1, Comparative Example 2, and Example 1 are all equal to about 24.3 μm.

The total opening rate of Comparative Example 1 is about 93.89%, and the total opening rate of Comparative Example 2 is about 94.92%. It can be seen that the opening rate of Comparative Example 2 of which the edge of the emission area is curved, and of which the emission area has a protruded corner portion (vertex), is greater than the opening rate of Comparative Example 1 of which the edge of the emission area is formed as a straight line.

Comparing Comparative Example 2 and Example 1, in Example 1, the edges of the emission area of the divided first subpixel P1 are concave, and the edges of the emission area of the second subpixel P2 and the third subpixel P3 are convex, while in Comparative Example 2, the edges of the emission area of the first subpixels P1 are convex, and the edges of the emission area of the second subpixel P2 and the third subpixel P3 are concave.

Referring to FIG. 9, the total opening rate of Example 1 is 95.55%, and the total opening rate of Comparative Example 2 is 94.92%. That is, it can be seen that the opening rate of Example 1 is greater than that of Comparative Example 2. To compare the total opening rate, the test of FIG. 9 was proceeded at a state wherein the opening rate of the first subpixel P1 of Comparative Example 2 and the opening rate of the first subpixel P1 of Example 1 are the same. That is, in a state wherein the emission areas of the first subpixel P1 of Comparative Example 2 are convex and the emission areas of the first subpixel P1 of Example 1 are concave, and the opening rate of the first subpixel P1 and the second subpixel P2 are the same, when the second subpixel P2 and the third subpixel P3 are formed such that the distance between the subpixels of Comparative Example 2 and Example 1 is about 24.3 μm, the size of the emission areas of the second subpixel P2 and the third subpixel P3 of Example 1 may be greater than that of Comparative Example 2.

In other words, when the emission area having a relatively small size among the emission areas included in the unit area is concave, while the emission area having a relatively great size is convex, the opening rate may be improved.

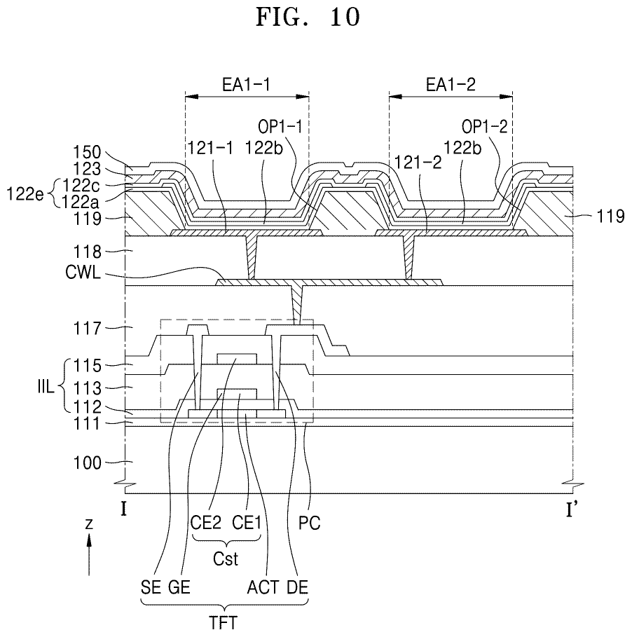

FIG. 10 is a cross-sectional view schematically illustrating a portion of a display apparatus, according to one or more embodiments. FIG. 10 is a cross-sectional view of a portion of the display apparatus in FIG. 7 taken along the line I-I′. In FIG. 10, the same reference numbers as those in FIG. 4 denote the same elements, and thus, redundant descriptions thereof are omitted.

Referring to FIG. 10 along with FIG. 7, the first subpixel P1 may include the first sub-subpixel P1-1 and the second sub-subpixel P1-2. The pixel electrode 121 of the first subpixel P1 may include a first sub pixel electrode 121-1 corresponding to the first sub-subpixel P1-1, and a second sub pixel electrode 121-2 corresponding to the second sub-subpixel P1-2. The pixel-defining layer 119 may include a first opening OP1-1 exposing at least a portion of the first sub pixel electrode 121-1 to define the first sub emission area EA1-1. The pixel-defining layer 119 may include a second opening OP1-2 exposing at least a portion of the second sub pixel electrode 121-2 to define the second sub emission area EA1-2. That is, the first sub pixel electrode 121-1 may correspond to the first sub emission area EA1-1, and the second sub pixel electrode 121-2 may correspond to the second sub emission area EA1-2.

In one or more embodiments, a connection line CWL may be located on the planarization layer 117. The connection line CWL may overlap at least a portion of the first sub pixel electrode 121-1 and the second sub pixel electrode 121-2 in the z direction. The connection line CWL may include a conductive material. An upper planarization layer 118 may cover the connection line CWL, and may be located on the planarization layer 117. The upper planarization layer 118 may include the same material as the planarization layer 117. The first sub pixel electrode 121-1 and the second sub pixel electrode 121-2 may be located on the upper planarization layer 118.

The first sub pixel electrode 121-1 and the second sub pixel electrode 121-2 may be electrically connected to the connection line CWL through a via hole of the upper planarization layer 118. Accordingly, the first sub pixel electrode 121-1 and the second sub pixel electrode 121-2 may be electrically connected to each other. The connection line CWL may be electrically connected to the thin-film transistor TFT by being in contact with the source electrode SE or the drain electrode DE through the via hole of the planarization layer 117. The first sub pixel electrode 121-1 and the second sub pixel electrode 121-2 may be electrically connected to the same pixel circuit PC. The first sub-subpixel P1-1 and the second sub-subpixel P1-2 may be driven by the same pixel circuit PC.

Unlike FIG. 10, in one or more embodiments, the first sub pixel electrode 121-1 and the second sub pixel electrode 121-2 may be integrally formed, and the connection line connecting the first sub pixel electrode 121-1 to the second sub pixel electrode 121-2 may be omitted.

According to one or more embodiments, the first subpixel, the second subpixel, and the third subpixel configured to emit light in different respective colors in the unit area UA may be spaced apart from each other. The first subpixel may include a first sub-subpixel and a second sub-subpixel that are smaller than the second subpixel and the third subpixel. The emission area of the first sub-subpixel and the second sub-subpixel may have concave edges, and the emission area of the second subpixel and the third subpixel may have convex edges. As a result, the deposition efficiency may be improved, thereby improving the opening rate of the pixel.

In the above, for convenience of explanation, an organic light-emitting diode as a display element was described to be included in the display apparatus. However, the embodiments of the disclosure may be applied to various display apparatuses, such as a liquid crystal display apparatus, an electrophoretic display apparatus, an inorganic electroluminescent (EL) display apparatus, etc.

The display apparatus according to the embodiments may be an electronic apparatus, such as a smartphone, a mobile phone, a navigation apparatus, a game machine, a television (TV), a vehicle head unit, a notebook computer, a laptop computer, a tablet computer, a personal media player (PMP), or a personal digital assistant (PDA). Also, the electronic apparatus may be a flexible apparatus.

According to the above, the display apparatus, in which the emission area is increased and the deposition efficiency in the manufacturing process is improved. However, the scope of the disclosure is not limited to these effects.

It should be understood that embodiments described herein should be considered in a descriptive sense only and not for purposes of limitation. Descriptions of aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims, with functional equivalents thereof to be included therein.

What is claimed is:

1. A display apparatus comprising:
a substrate comprising quadrilateral unit areas repeatedly arranged in a first direction, and in a second direction perpendicular to the first direction;
a first subpixel for emitting a first color, and comprising a first sub emission area and a second sub emission area spaced apart from each other at one of the unit areas;
a second subpixel for emitting a second color, and comprising a second emission area adjacent to the first sub emission area in the first direction at the one of the unit areas; and
a third subpixel for emitting a third color, and comprising a third emission area adjacent to the first sub emission area in the second direction at the one of the unit areas,
wherein the first sub emission area comprises a 1st-1 edge that generally extends in the first direction and that is concave, a 1st-2 edge that generally extends in the second direction and that is concave, and a first protrusion connecting the 1st-1 edge to the 1st-2 edge.

2. The display apparatus of claim 1, wherein the first protrusion is convex in a third direction crossing the first direction and the second direction.

3. The display apparatus of claim 1, wherein the first sub emission area is less than the second emission area and the third emission area.

4. The display apparatus of claim 1, wherein the second emission area comprises a 2nd-1 edge that generally extends in the first direction and that is convex, and a 2nd-2 edge that generally extends in the second direction and that is convex.

5. The display apparatus of claim 4, wherein the third emission area comprises a 3rd-1 edge that generally extends in the first direction and that is convex, and a 3rd-2 edge that generally extends in the second direction and that is convex.

6. The display apparatus of claim 5, wherein a length of the 2nd-1 edge is substantially equal to a length of the 2nd-2 edge, and
wherein a length of the 3rd-1 edge is substantially equal to a length of the 3rd-2 edge.

7. The display apparatus of claim 5, wherein the second emission area comprises a second protrusion at which the 2nd-1 edge and the 2nd-2 edge meet, and
wherein the third emission area comprises a third protrusion at which the 3rd-1 edge and the 3rd-2 edge meet.

8. The display apparatus of claim 7, wherein the second protrusion and the third protrusion each have a pointed shape in a third direction crossing the first direction and the second direction.

9. The display apparatus of claim 1, wherein a size of the second sub emission area is substantially equal to a size of the first sub emission area.

10. The display apparatus of claim 1, wherein the second sub emission area has a shape in which the first sub emission area is rotated by 90 degrees.

11. The display apparatus of claim 1, further comprising a pixel-defining layer above the substrate, covering at least a portion of a pixel electrode of the first subpixel, and defining openings defining the first sub emission area and the second sub emission area.

12. The display apparatus of claim 11, wherein the pixel electrode of the first subpixel comprises a first sub pixel electrode corresponding to the first sub emission area, and a second sub pixel electrode corresponding to the second sub emission area, and
wherein the first sub pixel electrode and the second sub pixel electrode are electrically connected to each other.

13. The display apparatus of claim 1, wherein the unit areas have a substantially square shape.

14. A display apparatus comprising:
a substrate comprising quadrilateral unit areas repeatedly arranged in a first direction, and in a second direction perpendicular to the first direction;
a first subpixel for emitting a first color, and comprising a first sub emission area and a second sub emission area spaced apart from each other at one of the unit areas;
a second subpixel for emitting a second color at the one of the unit areas, and comprising a second emission area having a size that is greater than a size of the first sub emission area; and
a third subpixel for emitting a third color at the one of the unit areas, and comprising a third emission area having a size that is greater than a size of the first sub emission area,
wherein the first sub emission area comprises a 1st-1 edge that generally extends in the first direction and that is convex, and a 1st-2 edge that generally extends in the second direction and that is convex,
wherein the second emission area comprises a 2nd-1 edge that generally extends in the first direction and that is convex, and a 2nd-2 edge that generally extends in the second direction and that is convex, and
wherein the third emission area comprises a 3rd-1 edge that generally extends in the first direction and that is convex, and a 3rd-2 edge that generally extends in the second direction and that is convex.

15. The display apparatus of claim 14, wherein the first sub emission area and the second sub emission area are adjacent to each other in a third direction crossing the first direction and the second direction, and
wherein the second emission area and the third emission area are adjacent to each other in a fourth direction that is perpendicular to the third direction.

16. The display apparatus of claim 14, wherein the second sub emission area has a shape in which the first sub emission area is rotated by 90 degrees.

17. The display apparatus of claim 14, wherein the first sub emission area comprises a first protrusion connecting the 1st-1 edge to the 1st-2 edge,
wherein the second emission area comprises a second protrusion at which the 2nd-1 edge and the 2nd-2 edge meet,
wherein the third emission area comprises a third protrusion at which the 3rd-1 edge and the 3rd-2 edge meet,
wherein the first protrusion is convex in a third direction crossing the first direction and the second direction, and
wherein the second protrusion and the third protrusion have a pointed shape in the third direction.

18. The display apparatus of claim 14, wherein a length of the 2nd-1 edge is substantially equal to a length of the 2nd-2 edge, and
wherein a length of the 3rd-1 edge is substantially equal to a length of the 3rd-2 edge.

19. The display apparatus of claim 14, further comprising a pixel-defining layer above the substrate, covering at least a portion of a pixel electrode of the first subpixel, and defining openings defining the first sub emission area and the second sub emission area.

20. The display apparatus of claim 19, wherein the pixel electrode of the first subpixel comprises a first sub pixel electrode corresponding to the first sub emission area, and a second sub pixel electrode corresponding to the second sub emission area, and
wherein the first sub pixel electrode and the second sub pixel electrode are electrically connected to each other.
